(19) United States
(12) Patent Application Publication
(10) Pub. No.: US 2007/0166952 A1
(43) Pub. Date: Jul. 19, 2007

(54) Dual isolation structure of semiconductor device and method of forming the same

(75) Inventor: Hyung Sun Yun, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/644,836

(22) Filed: Dec. 26, 2006

(30) Foreign Application Priority Data
Dec. 27, 2005 (KR) 10-2005-0130722

(51) Int. Cl. H01L 21/76; H01L 29/00

(52) U.S. Cl. 438/427; 257/506

(57) ABSTRACT

There are provided an isolation structure of a semiconductor device for suppressing the generation of leakage current by preventing two adjacent well regions below an isolation oxide layer from being electrically connected to each other, and a method of forming the same. The dual isolation structure of a semiconductor device is composed of a narrow and deep first isolation layer, and a wide and shallow second isolation layer. For example, the first isolation layer is a thermal oxide layer, and the second isolation layer is a chemical vapor deposition (CVD) layer. A first trench and a second trench are formed between adjacent well regions of the silicon substrate, and are buried with a first isolation layer and a second isolation layer respectively. A width of the first trench is smaller than that of the second trench, and a depth of the first trench is greater than that of the second trench. The second isolation layer is similar to a conventional isolation layer, and since the first isolation layer is formed deeper than the second isolation layer, adjacent well regions can be completely isolated.

### CLAIM OF PRIORITY UNDER 35 U.S.C. §119

The present application claims priority to Korean patent application No. KR 2005-0130722, filed in the Korean Patent Office on Dec. 27, 2005, the entire contents of which is hereby incorporated by reference herein.

### Field of the Invention

The present invention relates to a semiconductor device, and more particularly, to an isolation structure for a semiconductor device, and a method of making the same.

### BACKGROUND OF THE INVENTION

In order to fabricate a metal oxide semiconductor transistor (MOS transistor), local oxidation of silicon (LOCOS) technology or shallow trench isolation (STI) technology has been used to provide electrical isolation between adjacent devices. Recently, the STI technology has been widely used because the semiconductor device fabricated by the STI technology has relatively good isolation characteristics and a small occupation area with the demand for a high integration density semiconductor device.

FIGS. 1A through 1C are cross-sectional views illustrating a conventional isolation structure of a semiconductor device and a method of forming the same, in accordance with the prior art.

Referring to FIG. 1A, a pad oxide layer 11 and a pad nitride layer 12 are sequentially formed on a semiconductor substrate 10, and then, a photoresist pattern 13 defining an isolation region is formed on the pad nitride layer 12. Then, a trench 14 with a predetermined depth is formed in the silicon substrate 10 by sequentially etching the pad nitride layer 12, the pad oxide layer 11, and the silicon substrate 10 using the photoresist pattern 13 as a mask.

After removing the photoresist pattern 13, an isolation oxide layer 15 is deposited on the entire surface of the silicon substrate 10 to fill the trench 14 as shown in FIG. 1B. Thereafter, a chemical mechanical polishing (CMP) process is performed to remove the isolation oxide layer 15 on the pad nitride layer 12, and make the isolation oxide layer 15 remain only inside the trench 14.

Subsequently, the pad nitride layer 12 and the pad oxide layer 11 are removed, to thereby complete an isolation structure as shown in FIG. 1C. Thereafter, well ion implantation processes are respectively performed to an NMOS region and a PMOS region, to thereby form an n-type well region 16a and a p-type well region 16b respectively.

In the conventional isolation structure described above and shown in FIG. 1C, the two adjacent well regions 16a and 16b are electrically connected to each other 17 below the isolation oxide layer 15. Because of this, leakage currents are generated between the well regions, between the active regions, and between the well region and the active region, to thereby deteriorate the performance of devices and badly influence on the reliability of devices.

### SUMMARY OF THE INVENTION

It is, therefore, an object of the present invention to provide an isolation structure for a semiconductor device that suppresses the generation of leakage current by preventing two adjacent well regions below an isolation oxide layer from being electrically connected to each other, and a method of fabricating the same.

In accordance with an embodiment of the present invention, there is provided a dual isolation structure of a semiconductor device. The dual isolation structure comprises a first trench formed between adjacent well regions of a silicon substrate, the first trench having a first width and a first depth and a first isolation oxide layer deposited in at least a portion of the first trench. The dual isolation structure also comprises a second trench formed between the adjacent well regions of the silicon substrate, the second trench having a second width and a second depth and a second isolation oxide layer deposited in at least a portion of the second trench. The first width is smaller than and encompassed by the second width, and the first depth is greater than the second depth.

Additionally, the first depth may be greater than a depth of the well region. Further, the first isolation oxide layer may be a thermal oxide layer, and the second isolation oxide layer may be a chemical vapor deposition (CVD) oxide layer.

In accordance with another embodiment of the present invention, a method of forming a dual structure of a semiconductor device is provided, The method comprises selectively etching a predetermined region of a silicon substrate, to thereby form a first trench having a first width and a first depth and forming a first isolation oxide layer in at least a portion of the first trench. The method additionally comprises selectively etching the predetermined region of the silicon substrate, to thereby form a second trench having a second width that is larger than and encompasses the first width and a second depth that is less than the first depth and forming a second isolation oxide layer in at least a portion of the second trench.

The forming of the first trench and the forming of the second trench may be performed using a dry etching process, and the forming of the first isolation oxide layer may be performed using a thermal oxidation process. Further, the forming of the second isolation oxide layer may comprise depositing the second isolation oxide layer on the entire surface of the silicon substrate using a chemical vapor deposition (CVD) process, and performing a chemical mechanical polishing (CMP) process so that the second isolation oxide layer remains only in an interior region of the second trench.

### BRIEF DESCRIPTION OF THE DRAWINGS

The above and other objects and features of the present invention will become apparent from the following description of preferred embodiments given in conjunction with the accompanying drawings, in which:

FIGS. 1A through 1C are sectional views illustrating a conventional isolation structure of a semiconductor device and a method of forming the same, in accordance with the prior art; and

FIGS. 2A through 2E are sectional views illustrating a dual isolation structure of a semiconductor device and a method of forming the same, in accordance with an embodiment of the present invention.

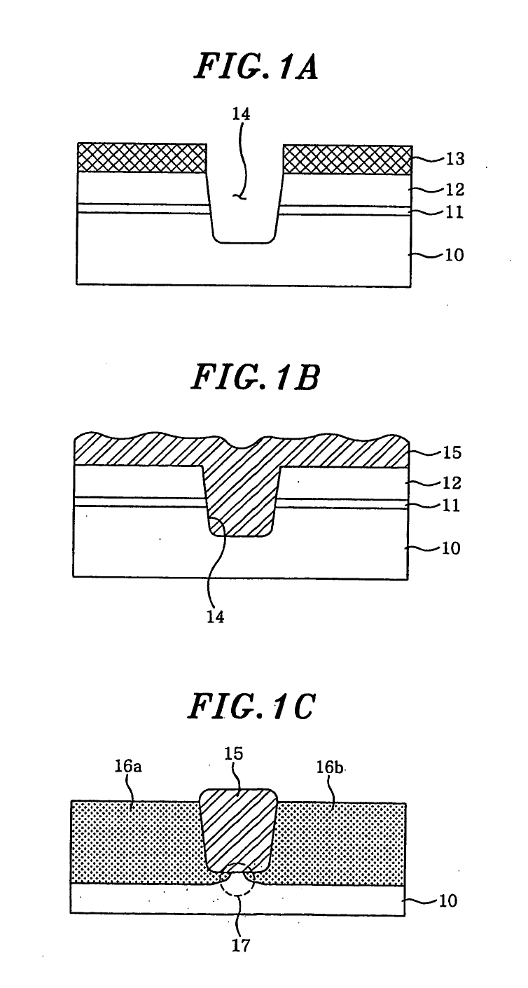

### DETAILED DESCRIPTION OF THE PREFERRED EMBODIMENTS

Hereinafter, preferred embodiments of the present invention will be described in detail with reference to the accompanying drawings so that they can be readily implemented by those skilled in the art. In describing the embodiments of the present invention, descriptions of the technical contents which are well-known in the technical field to which the present invention pertains and which are not directly related to the present invention are not described herein to avoid redundancy by describing matters well-known to those skilled in the relevant art. In addition, some constituents may be exaggerated, omitted or schematically illustrated in drawings attached to the present application such that the dimension of each constituent does not entirely reflect the actual dimension thereof.

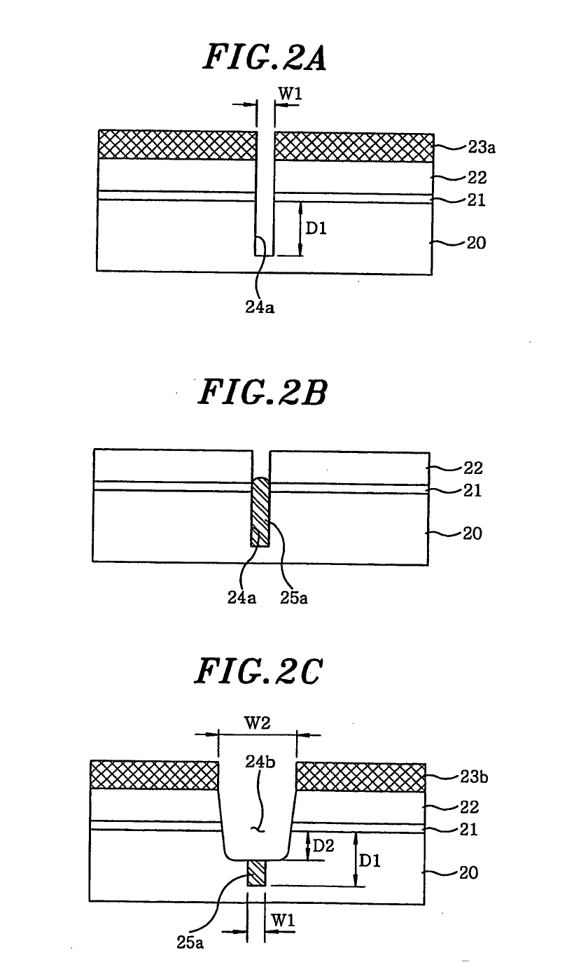

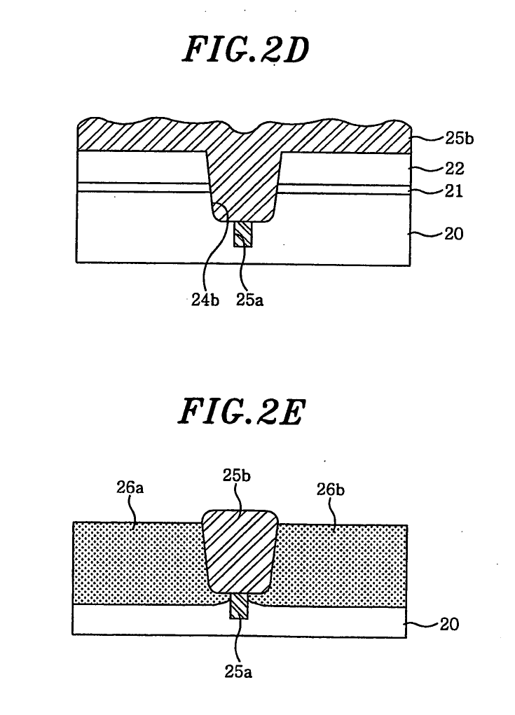

FIGS. 2A through 2E are cross-sectional views illustrating a dual isolation structure of a semiconductor device and a method of forming the same, according to an embodiment of the present invention.

Referring to FIG. 2A, after a pad oxide layer 21 and a pad nitride layer 22 are sequentially formed on a silicon substrate 20, a first photoresist pattern 23a is formed on the pad nitride layer 22. Thereafter, the pad nitride layer 22, the pad oxide layer 21, and the silicon substrate 20 are sequentially etched using the first photoresist pattern 23a as a mask, to thereby form a first trench 24a with a first width W1 and a first depth D1 in the silicon substrate 20. The etching process of forming the first trench 24a may be performed using a dry etching process such as a reactive ion etching (RIE) process.

Subsequently, a wet or dry type thermal oxidation process is performed to form a first isolation oxide layer 25a that fills the inside of the first trench 24a as shown in FIG. 2B. That is, the first isolation oxide layer 25a is a thermal oxide layer.

Subsequently, a second photoresist pattern 23b is formed on the pad nitride layer 22 as shown in FIG. 2C. The pad nitride layer 22, the pad oxide layer 21, and the silicon substrate 20 are sequentially etched using the second photoresist pattern 23b as a mask, to thereby form a second trench 24b with a second width W2 and a second depth D2 in the silicon substrate 20. At this time, the width W2 of the second trench 24b is greater than the width W1 of the first trench 24a, and the depth D2 of the second trench 24b is smaller than the depth D1 of the first trench 24a. The etching of the second trench 24b is performed using a dry etching process such as a RIE process.

Then, after removing the second photoresist pattern 23b, a second isolation oxide layer 25b that fills the second trench 24b is deposited on the entire surface of the silicon substrate 20 as shown in FIG. 2D. The second isolation oxide layer 25b is a chemical vapor deposition (CVD) oxide layer formed by, for example, a high-density plasma chemical vapor deposition (HDP-CVD) process.

Subsequently, a chemical mechanical polishing (CMP) process is performed to remove the second isolation oxide layer 25b from the pad nitride layer 22, so that the second isolation oxide layer 25b is remained only inside the second trench 24b. Then, the remaining pad nitride layer 22 and the remaining pad oxide layer 21 are removed, to thereby complete formation of a dual isolation structure as shown in FIG. 2E. Then, well ion implantation processes are respectively performed to an NMOS region and a PMOS region, to thereby form an n-type well region 26a and a p-type well region 26b respectively.

As described above, a dual isolation structure is formed that comprises a narrow and deep first isolation layer, and a wide and shallow second isolation layer, according to an embodiment of the present invention. The second isolation layer is similar to the conventional isolation layer, and the first isolation layer can completely isolate adjacent well regions because the first isolation layer is formed deeper than the second isolation layer. Therefore, generation of leakage current between well regions, between active regions, and between the well region and the active region can be effectively prevented, and the performance of an associated device and the reliability of an associated device can be improved.

While the invention has been shown and described along with accompanying drawings using specific terms with respect to the preferred embodiment, but the terms are intended to explain the technological spirit of the present invention more easily and help the better understanding thereof, but they are not intended to confine the scope of the present invention. It will be understood by those skilled in the art that various changes and modifications may be made without departing from the spirit and scope of the invention as defined in the following claims.

What is claimed is:

1. A dual isolation structure of a semiconductor device comprising:
a first trench formed between adjacent well regions of a silicon substrate, the first trench having a first width and a first depth;
a first isolation oxide layer deposited in at least a portion of the first trench;
a second trench formed between the adjacent well regions of the silicon substrate, the second trench having a second width and a second depth; and
a second isolation oxide layer deposited in at least a portion of the second trench, wherein the first width is smaller than and encompassed by the second width, and the first depth is greater than the second depth.

2. The dual isolation structure of claim 1, wherein the first depth is greater than a depth of the well region.

3. The dual isolation structure of claim 1, wherein the first isolation oxide layer is a thermal oxide layer.

4. The dual isolation structure of claim 1, wherein the second isolation oxide layer is a chemical vapor deposition (CVD) oxide layer.

5. A method of forming a dual structure of a semiconductor device comprising:
selectively etching a predetermined region of a silicon substrate, to thereby form a first trench having a first width and a first depth;
forming a first isolation oxide layer in at least a portion of the first trench;
selectively etching the predetermined region of the silicon substrate, to thereby form a second trench having a second width that is larger than and encompasses the first width and a second depth that is less than the first depth; and
forming a second isolation oxide layer in at least a portion of the second trench.

6. The method of claim 5, wherein the forming of the first trench and the forming of the second trench are performed using a dry etching process.

7. The method of claim 5, wherein the forming of the first isolation oxide layer is performed using a thermal oxidation process.

8. The method of claim 5, wherein the forming of the second isolation oxide layer comprises depositing the second isolation oxide layer on the entire surface of the silicon substrate using a chemical vapor deposition (CVD) process, and performing a chemical mechanical polishing (CMP) process so that the second isolation oxide layer remains only in an interior region of the second trench.
